(19) United States
(12) Patent Application Publication
(10) Pub. No.: US 2015/0116961 A1
(43) Pub. Date: Apr. 30, 2015

(54) METHOD AND STRUCTURE FOR INHIBITING DENDRITE FORMATION

(71) Applicant: Lakshminarayan Viswanathan, Phoenix, AZ (US)

(72) Inventor: Lakshminarayan Viswanathan, Phoenix, AZ (US)

(21) Appl. No.: 14/066,689

(22) Filed: Oct. 30, 2013

(51) Int. Cl. H05K 1/02; H05K 1/18; H05K 1/11; H05K 3/46

(52) U.S. Cl. CPC H05K 1/0213; H05K 3/46; H05K 1/181; H05K 1/115; H05K 2201/10015; H05K 2201/10022; H05K 2201/20
USPC 361/760; 29/825; 361/748

(57) ABSTRACT

A circuit includes a structure for inhibiting dendrite formation. The circuit includes a first electrode disposed within a first area of the circuit, wherein the first electrode is configured to be coupled to an ionic source that forms ions when a first electric potential is applied to the first electrode. The circuit also includes a second electrode disposed within a second area of the circuit. The second electrode is configured to receive a second electric potential that is less than the first electric potential and that causes the ions to migrate toward the second electrode to contribute to dendrite formation. The circuit further includes a structure disposed within a third area of the circuit. The structure is configured to receive a third electric potential to create a barrier that inhibits the migration of at least some of the ions from the first to the second electrode to inhibit dendrite formation.

### FIELD

The present disclosure relates generally to electrical and electronic circuits and more particularly to a method and structure for inhibiting dendrite formation and growth in such circuits.

### BACKGROUND

The occurrence of metal migration and corresponding dendrite formation in the electronics industry is a common phenomenon. Metal migration is fundamentally an ionic transport process requiring an electrolyte, an electrical bias between closely spaced electrodes or conductors, for instance, and time.

In a particular scenario involving positive and negative electrodes in the presence of an ion transport layer such as water or some other liquid or solid electrolyte, a metal that is close to, coupled to, or included within the positive electrode oxidizes to create metal ions upon application of a potential difference or bias between the positive and negative electrodes. These metal ions are transported or migrate, under the applied bias, through the ion transport layer to the negative electrode and eventually electrodeposit on the negative electrode forming a dendrite at, on, or near the negative electrode. As the dendrite grows, the gap between the two electrodes narrows and can, eventually, be bridged by the dendrite leading to an electrical failure involving, for instance, shorts in an electronic system or system shutdown.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a block diagram illustrating a circuit that includes a structure for inhibiting dendrite formation, in accordance with an embodiment.

FIG. 2 is a block diagram illustrating a topside view of a circuit that includes a structure for inhibiting dendrite formation, in accordance with an embodiment.

FIG. 3 is a schematic diagram illustrating a circuit that includes multiple structures for inhibiting dendrite formation, in accordance with an embodiment.

FIG. 4 is a flow diagram illustrating a method for forming a circuit that includes a structure for inhibiting dendrite formation, in accordance with an embodiment.

The present disclosure is illustrated by way of example and is not limited by the accompanying figures, in which like reference numbers indicate similar elements. Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

The apparatus and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein. Also, the functions included in the flow diagrams do not imply a required order of performing the functionality contained therein.

### DETAILED DESCRIPTION

In accordance with one particular embodiment is a circuit having a structure for inhibiting dendrite formation. The circuit includes a first electrode disposed within a first area of the circuit, wherein the first electrode is configured to be coupled to an ionic source that forms ions when a first electric potential is applied to the first electrode. The circuit also includes a second electrode disposed within a second area of the circuit. The second electrode is configured to receive a second electric potential that is less than the first electric potential and that causes the ions to migrate toward the second electrode to contribute to dendrite formation. The circuit further includes a structure disposed within a third area of the circuit. The structure is configured to receive a third electric potential to create a barrier that inhibits the migration of at least some of the ions from the first electrode to the second electrode to inhibit the dendrite formation.

In accordance with another embodiment is a method of manufacturing a circuit having a structure for inhibiting dendrite formation. The method includes forming a first electrode within a first area of the circuit, and forming a second electrode within a second area of the circuit. The first electrode is configured to be coupled to an ionic source that forms ions when a first electric potential is applied to the first electrode. The method also includes forming a structural barrier between the first and second electrodes to, when a second electric potential is applied to the structural barrier, inhibit the migration of at least some of the ions toward the second electrode in order to inhibit dendrite formation at the second electrode.

Forming circuits to have structures, in accordance with the present teaching, for inhibiting dendrite formation can provide some illustrative benefits. For example, simple structures such as the inclusion of additional electrodes and trace lines can be formed in the circuit for inhibiting dendrite formation. Moreover, the present teachings can be applied to multiple types of circuits having multiple components and electrodes that may present a dendrite growth problem under certain conditions. Moreover, implementation of the present innovation enables the use within a circuit of attractive bonding metals like silver, notwithstanding such metals being characterized by a propensity for causing dendrite formation.

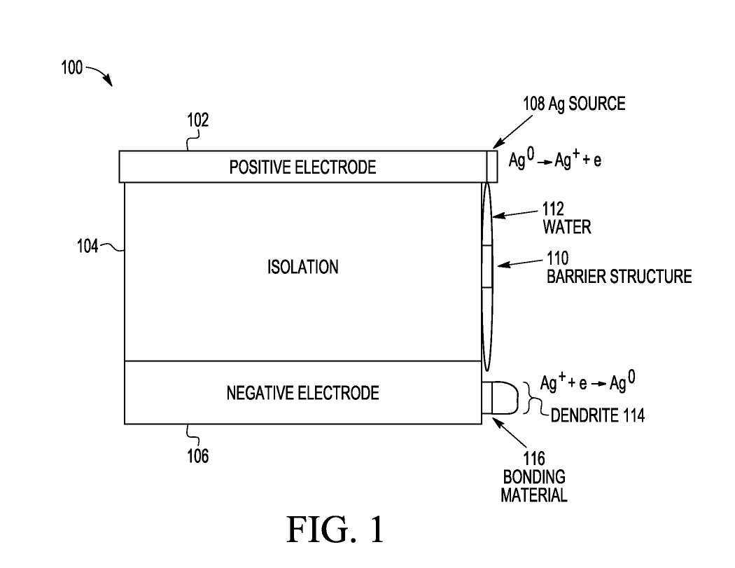

Turning now to a detailed description of the figures. Illustrated in FIG. 1 is cross-sectional view of a circuit 100 that includes a structure 110 for inhibiting dendrite formation, in accordance with an embodiment. The circuit can be, for example, part of an IC, a PCB, or a discrete electronic component. As used herein, a circuit at a minimum includes two electrodes or conductors and a barrier structure, also referred to herein as a structure, a barrier, and a structural barrier. In accordance with the present teachings, the barrier structure inhibits the migration of ions generated by an ionic source, in order to inhibit dendrite formation. To inhibit dendrite formation means to at least restrain, hinder, or decrease the rate of dendrite formation and, in some instances, may mean to stop or prevent the dendrite formation.

More particularly with respect to FIG. 1, circuit 100 includes: a first electrode 102 disposed within a first area of the circuit 100; a second electrode 106 disposed within a second area of the circuit 100; and the barrier structure 110 disposed within a third area of the circuit 100. In this case, the electrodes 102 and 106 and the barrier structure 110 are formed on, into, or otherwise coupled to isolation 104 within the circuit 100. The particular type of material used to create the electrodes 102 and 106, barrier structure 110, and isolation 104 depends upon the type of circuit 100 that includes these elements. For instance, the circuit 100 can be formed on, made of, or include at least one of, but not limited to, a printed circuit board (PCB), a discrete electronic component, an integrated circuit (IC), multi-layer ceramic carriers for electronics, electrochemical cells, etc.

In one example implementation, the circuit 100 includes a multi-layer PCB having at least one conductive layer, such as a metal layer, and at least one isolation layer, e.g., the isolation 104, separating or between the conductive layers. As used herein, a PCB includes any type of circuit board that supports and electrically connects electronic components. Accordingly, different materials can be used to form the isolation 104 in a PCB including, but not limited to, organic material such as a polymer, inorganic material such as ceramic, and/or a combination of organic and inorganic material.

In one embodiment, the electrodes 102 and 106 and barrier structure 110 are formed in one or more of the conductive layers of the PCB. For example, the electrodes 102 and 106 are pads on a surface or uppermost top layer of the PCB. The electrode 102 is a positive electrode configured to receive a positive electric potential, e.g., a positive voltage V+. The electrode 106 is a negative electrode configured to receive an electric potential that is less than the electric potential applied to the positive electrode 102 during operation and in one embodiment is around zero volts, 0V. Alternatively, the electrodes 102 and 106 are part of a component embedded in the PCB, such as occurs with some advanced PCBs. Moreover, the material used to construct the electrodes 102 and 106 can be any material typically used to fashion the conductive layers of a PCB including, but not limited to, copper, any metal plated with nickel or gold, a copper and silver alloy, etc.

In a different embodiment, the circuit 100 is a discrete electronic component such as a capacitor, a resistor, or an active component, which can be, in one example, a ceramic component. The electronic component 100 includes: an anode 102 having a positive polarity, wherein the anode 102 is disposed in a first layer of the electronic component 100; and a cathode 106 having a polarity that attracts positively charged ions, i.e., cations, wherein the cathode 106 is disposed in a second layer of the electronic component 100. The anode 102 and the cathode 106 are separated by the isolation 104. In yet another embodiment, the electrodes 102 and 106 are disposed within an IC and can be pads on the surface of the IC or electrodes of a component embedded within the IC. In such a case, the electrodes 102 and 106 can be constructed with metal from one or more conductive layers of the IC. Moreover, the electrodes 102 and 106 are separate by isolation 104, which can be a substrate formed using a semiconductor material or can be a nonconductive dielectric material.

Also included in the circuit 100 is an ionic source 108 coupled to the electrode 102 that forms or is susceptible to forming ions when exposed to the potential applied to the electrode 102. The ionic source 108 can be “coupled” to the electrode 102 by being formed on or applied to the electrode 102. For instance, where the electrode 102 is a pad of a PCB, the ionic source is a bonding material such as a solder material applied to the pad 102 to mount an electronic device, such as an electronic component or an IC chip, to the PCB; and the bonding material is made of a material that oxidizes to form ions when the positive electric potential is applied to the electrode 102. In one embodiment, the ionic source 108 is constructed at least in part using a conductive material, which forms the ions. Examples of conductive materials include, for instance, metal alloys, conductive epoxies, metal and polymer combinations, and metal and ceramic combinations. Accordingly, in one particular embodiment, the ionic source 108 is made, at least in part, from a metal, which forms the ions. For example, the metal can be silver as illustrated in FIG. 1, and the ionic source 108 can be a conductive epoxy with silver or can be silver in any type of metal and polymer or ceramic combination. In other implementations, the metal can be copper, tin, gold, etc., or some combination of metals such as a copper and silver alloy.

Alternatively, the ionic source 108 can be “coupled” to the electrode 102 by being integrated with or being a part of or one with the electrode 102. This is the case, for instance, where the electrode 102 is embedded in the circuit 100 and is fabricated from a material, e.g., a metal or metal combination, such as any of those listed above, which has a propensity to generate ions when an electric potential is applied to the electrode 102 and/or an electrical bias is applied across the electrodes 102 and 106.

Turning again to the specific illustration provided by reference to FIG. 1. As shown, the metal silver is used at least in part to fabricate the ionic source 108. Accordingly, when a positive potential, e.g., V⁺, is applied to the positive electrode 102, silver, Ag⁰, ionizes into Ag⁺ cations plus an electron, e. In the presence of an ionic transport layer, which is an electrolytic medium by which ions can migrate, such as a mono-layer of water 112 created by humidity and condensation or any other electrolytic medium including a solid electrolyte, the Ag⁺ cations are attracted to and migrate toward the negative electrode 106 when a potential sufficiently less than V⁺ is applied to the negative electrode 106. Under conditions that lack the presence of the innovative teachings, as the Ag⁺ cations migrate to electrode 106, they combine with electrons present at or near the electrode 106 to form a silver dendrite or growth 114 at the electrode 106. In one example implementation, the dendrite 114 grows directly on the electrode 106. In another embodiment, a bonding material 116 such as solder is also applied to or is integrated within the electrode 106, and the dendrite 114 grows on the bonding material 116.

The rate at which the dendrite 114 grows depend on conditions within and surrounding the circuit 100 including, but not limited to: the position in the electrochemical series of the ion generating material within the ionic source 108, which influences an amount of oxidation; the potential difference between electrodes 102 and 106, which influences a rate of oxidation; the type and concentration of the ionic transport layer and temperature, which influence a rate of ion migration; and the presence of contaminants within the ionic transport layer, which may speed up the dendrite formation process. As mentioned earlier, over time, the dendrite 114 can grow until it couples back to the electrode 102, where it can cause electrical shorts that can lead to system failure.

In accordance with the present teachings, however, the structure 110 is formed or disposed within a third area of the circuit 100. The structure 110 is configured to receive an electric potential in order to create a barrier that inhibits the migration and contribution to the dendrite 114 formation of at least some of the Ag⁺ cations. In order to create the barrier to ion migration, and hence can inhibit dendrite formation, the structure 110 is constructed using a material that is less susceptible or more resistant to forming ions and/or dendrites than the material used to construct the ionic source 108. The material used to construct the barrier structure 110 may be, under the conditions within or surrounding the circuit 100, less susceptible or more resistant to ion formation because of its position in the electrochemical serial and/or because of an applied coating that inhibits oxidation of the material. The material may, alternatively, be less susceptible or more resistant to dendrite formation even where ions are generated where the ions are not soluble in or do not otherwise easily migrate using the particular ion transport layer that is present in the circuit 100. Accordingly, in an embodiment, the material used to form the structure itself inhibits dendrite formation.

To further create the barrier to ion migration, and hence inhibit dendrite formation, the electric potential applied to the structure 110 is, in one embodiment, substantially the same as or is greater than the electric potential applied to the electrode 102. Accordingly, since the structure 110 is positioned or located in an area between the electrodes 102 and 106, the electric potential applied to the structure 110 acts to at least lessen and may stop the tendency of the cations to be attracted toward the electrode 106. In other words, the structural barrier 110 is dimensioned and/or positioned relative to the electrode 102 and/or 106 to create a “cage” of voltage that surrounds or partially surrounds the ionic source 108 or to create a “barrier” of voltage that otherwise blocks or inhibits ion migration along, through, or over an ion transport path between the ionic source 108 and the electrode 106.

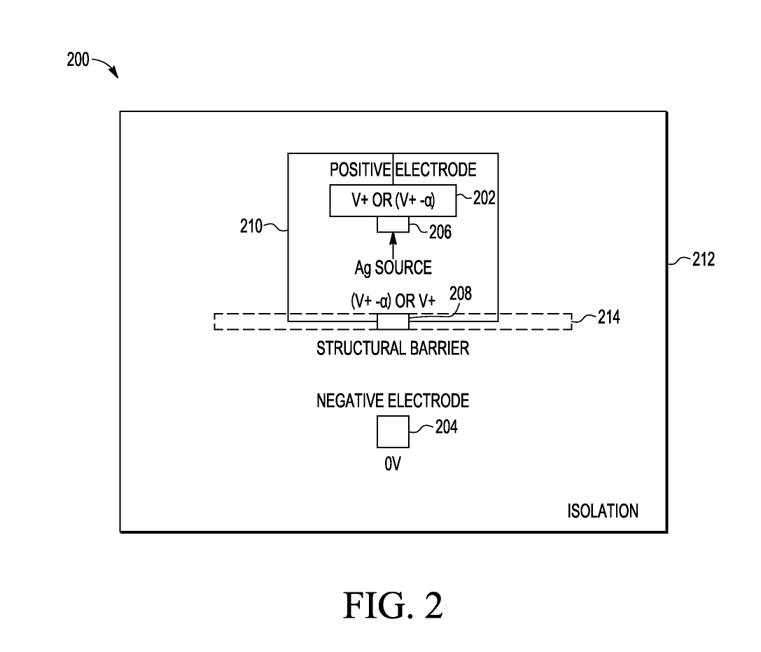

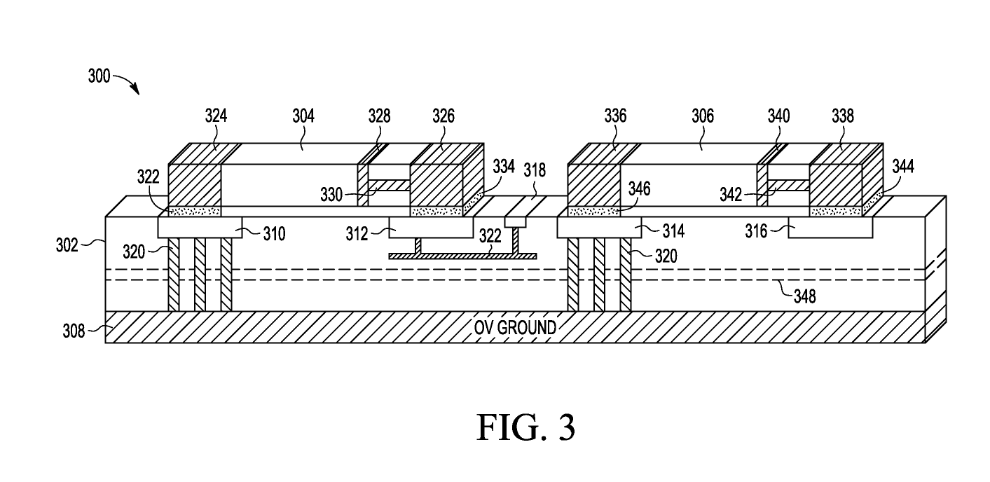

The particular dimensions and/or position of the structural barrier 110 within the circuit 100 depends, at least in part, on how the electrodes 102 and 106 are relationally positioned with respect to each other such as whether the first area in which the electrode 102 is disposed and the second area in which the electrode 106 is disposed are located in a same plane or a different plane of the circuit 100. FIGS. 2 and 3 illustrate different embodiments of positioning a barrier structure within a circuit having two electrodes that are spaced closely enough to enable dendrite formation to occur under certain conditions.

More particularly, FIG. 2 illustrates an embodiment of placement of a barrier structure within or on a two-dimensional surface. Shown therein is a top-side view circuit 200 that includes a positive electrode 202 disposed within a first area of the circuit 200, a negative electrode 204 disposed within a second area of the circuit 200, and an ionic, in this case silver, source 206 coupled to the electrode 202. For example, electrodes 202 and 204 and silver source 206 are disposed within a surface, top, or uppermost isolation layer 212 of a PCB or IC 200. In this embodiment, the first and second areas are in a same plane of the circuit 200, and a structural barrier 208, 210 is formed in a third area of the circuit 200. The third area is in the same plane as the first and second areas that contain the electrodes 202 and 204, respectively.

In the embodiment illustrated, the structural barrier includes a third electrode or conductive element 208 and a set of conductive lines 210 connecting the first 202 and third 208 electrodes. Accordingly, in this embodiment, first electrode 202 is electrically connected to the structure 208, 210, in this instance using the conductive lines 210. The electrode 208 and conductive lines 210 can be made from the same material as the electrodes 202 and/or 204, such as copper or some other metal or metal alloy, or can be made from a different material than one or both of the electrodes 202 and 204.

As illustrated, during operation, a first electric potential is applied to the first electrode 202, a second electric potential is applied to the second electrode 204, and a third electric potential is applied to the third electrode 208. In this embodiment, the electrode 204 is coupled to receive around 0V. By virtue of the conductive lines 210 electrically connecting the first 202 and third 208 electrodes, the electric potentials applied to these two electrodes are substantially the same, with the difference being based on the resistance in the conductive lines 210 between the electrodes 202 and 208. Thus, where an electric potential V⁺ is applied to the electrode 208, the electric potential at or applied to the electrode 202 is (V⁺−∂), where −∂ is caused by and represents the resistance in the conductive lines 210. Alternatively, where an electric potential V⁺ is applied to the electrode 202, the electric potential at or applied to the electrode 208 is (V⁺−∂), where −∂ is caused by and represents the resistance in the conductive lines 210. Thus, in this instance, the electrode 208 and conductive lines 210 create a cage of voltage at about V⁺ around the silver source 206.

In a different embodiment, the electrodes 202 and 208 are not electrically connected. However, the electrode 208 is supplied substantially the same as or a greater electric potential than the electric potential supplied to the electrode 202. In this case, to create a larger barrier of voltage to inhibit ion migration from the silver source 206 to the electrode 204, the area of electrode 208 can be increased in any suitable manner, for instance as shown at 214.

FIG. 3 illustrates an embodiment of placement of a barrier structure within a three-dimensional circuit topology. Shown therein is perspective view that shows a cut-away portion of a circuit 300 having an electronic component 304 and an electronic component 306 mounted to a PCB 302. The PCB 302 is a multi-layered PCB having at least one metal layer and at least one isolation layer, e.g., an organic layer, a ceramic layer, etc. As shown, the PCB 302 includes a voltage common or ground layer 308 that is maintained at around 0V. The PCB 302 further includes a top layer having disposed therein electrodes 310-318 that are constructed using a material that includes a metal, at least in part. The electrodes 310 and 314 are electrically connected to the ground plane 308 using vias 320. The electrodes 312 and 316 are electrically connected to a voltage source (not shown) to receive a positive voltage V⁺. The electrode 318 is electrically connected to the electrode 312 using conductive lines 322.

Component 304 includes: an anode 326 disposed in a first area of the electronic component 304; a cathode 324 disposed in a second area of the electronic component 304; and a barrier structure 328 disposed in a third area of the electronic component 304 between the first and second areas. The barrier structure 328, in this case, is constructed using a material that is resistant to ion formation, and the barrier structure 328 is configured to be electrically connected to the anode 326 using a conductive line 330. The anode 326 of the component 304 is mounted to the electrode 312 using a conductive material, e.g., a conductive epoxy, 334 such that the anode 326 is electrically connected to the voltage source (not shown). The cathode 324 of the component 304 is mounted to the electrode 310 using a conductive material 332 such that the cathode 324 is electrically connected to the ground plane 308.

Component 306 includes: an anode 338 disposed in a first area of the electronic component 306; a cathode 336 disposed in a second area of the electronic component 306; and a barrier structure 340 disposed in a third area of the electronic component 306 between the first and second areas. The barrier structure 340, in this case, is constructed using a material that is resistant to ion formation, and the barrier structure 340 is configured to be electrically connected to the anode 338 using a conductive line 342. The anode 338 of the component 306 is mounted to the electrode 316 using a conductive material 344 such that the anode 338 is electrically connected to the voltage source (not shown). The cathode 336 of the component 306 is mounted to the electrode 314 using a conductive material 346 such that the cathode 336 is electrically connected to the ground plane 308. In this case, at least the conductive material 332, 334, 344, and 346 provides an ionic source that has a propensity to generate ions that may form dendrites in the absence of a barrier structure in accordance with the present teachings. One or more of the electrodes 324, 326, 336, and 338 may also provide an ionic source that can lead to dendrite formation in the absence of a barrier structure in accordance with the present teachings.

FIG. 3 illustrates various embodiments of a circuit having a structure, in accordance with the present teachings, for inhibiting dendrite formation. In one embodiment, the electrodes and the barrier structure are included on a same plane of a circuit, in this case of the PCB 302. More particularly, the electrodes 312 and 314, and the electrode 318 of the barrier structure 318, 322 are disposed on the surface plane of the PCB 302. In this example, the circuit 300 includes multiple electronic components, e.g., 304 and 306, wherein the electrodes 312 and 314 are coupled to different electronic components of the circuit 300. Accordingly, the barrier structure 318, 322, is configured to inhibit ion migration from the ionic source 334 to the electrode 314.

In other embodiments, the electrodes and the barrier structure are included in different planes of a circuit, in this case of the PCB 302 and the discrete electronic components 304 and 306. In the example of the PCB 302, a barrier structure 348 can be formed in a layer embedded in the PCB 302 to inhibit ion migration along a path, for instance through the PCB 302, between the ionic sources 334 and/or 344 coupled to positive electrodes 312 and 316, respectively, toward the ground plane 308. In accordance with this illustrative implementation, a first electrode, e.g., 312 or 316, is disposed in a surface layer of the printed circuit board 302, a second electrode 308 is disposed in a ground layer 308 of the printed circuit board 302, and the barrier structure 348 is disposed in a layer of the printed circuit board 302 between the surface layer and the ground layer 308. In one embodiment, the barrier structure 348 is electrically connected to the positive electrode 312 and/or 316. However, such an electrical connection is not required.

In the example of the electronic components 304 and 306, the positive electrode, 326, 338, and the negative electrode, 324, 336, of the electronic components 304 and 306, respectively, are disposed in different areas of the electronic circuit as shown. The barrier structures 328, 340 of the electronic components 304 and 306, respectively, are disposed in yet another area of the corresponding electronic components. Accordingly, the barrier structure 328, 330 of the electronic component 304 is configured to inhibit or block the migration along a path, for instance through the component 304 or along the side of the component 304, toward the cathode 324 of ions that might be generated from the material used to construct the anode 326. Similarly, the barrier structure 340, 342 of the electronic component 306 is configured to inhibit or block the migration along a path, for instance through the component 306 or along the side of the component 306, toward the cathode 336 of ions that might be generated from the material used to construct the anode 338.

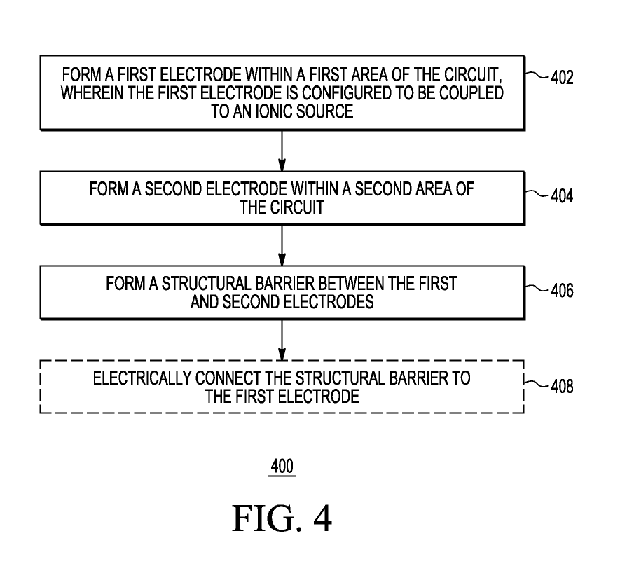

Turning now to FIG. 4, illustrated therein is a flow diagram 400 illustrating a method for forming or manufacturing a circuit that includes a structure for inhibiting dendrite formation, in accordance with an embodiment. As mentioned above, the circuit could include elements formed in or mounted to a PCB, elements formed in an IC, and/or elements formed in a discrete electronic component. Accordingly, the type of circuit manufacturing or fabrication technique used depends on the type of circuit being formed. Example manufacturing or fabrication techniques include, but are not limited to, a semiconductor manufacturing process, a multi-layer or single layer organic board manufacturing process, a ceramic multi-layer or single layer board manufacturing process, a sputtering process, an ink jet process, or a compact disc (CD) substrate printing process, to name a few.

Now regarding the details of the flow diagram 400, the process of manufacturing or fabricating the circuit having the barrier structure involves forming 402 a first electrode within a first area of a circuit, wherein the first electrode is configured to couple to an ionic source that forms ions when a first electric potential is applied to the first electrode. The coupling between the first electrode and the ionic source could, for instance, result from the ionic source being formed on or applied to the first electrode, such as when a bonding material is applied to a pad of a PCB or IC. Alternatively, the coupling between the first electrode and the ionic source results from the first electrode itself being the ionic source. The process further involves forming 404 a second electrode within a second area of the circuit. Additionally, the process involves forming 406 a structural barrier between the first and second electrodes.

For instance, as described by reference to electrodes 202 and 204 and structural barrier 208, 210 of circuit 200 and electrodes 312 and 314 and structural barrier 318, 322 of PCB 302, the first and second electrodes and the structural barrier are formed on a surface of the circuit. The surface of the circuit can be the surface of a PCB as shown in FIG. 3 or the surface of an IC, as examples. Where the circuit is a multi-layer circuit such as a multi-layer PCB or a multi-layer discrete electronic component or a multi-layer IC, the first and second electrodes and the structural barrier can be formed in different layers of the multi-layer circuit. FIG. 3 shows multiple examples of this implementation. More particularly, first electrode 312 and/or 316, second electrode 308, and structural barrier 348 are formed in the multi-layer PCB 302. Also, first electrode 338, second electrode 336, and structural barrier 340, 342 are formed in the multi-layer component 306. Similarly, first electrode 326, second electrode 324, and structural barrier 328, 330 are formed in the multi-layer component 304.

In a further embodiment, forming the structural barrier comprises forming a third electrode and forming a set of one or more conductive lines between the first and third electrodes. This embodiment is shown, for example, by reference to FIG. 2, wherein the structural barrier includes a third electrode 208 and conductive lines 210 formed between the third electrode 208 and the first electrode 202. This embodiment is further shown, for example, by reference to FIG. 3 wherein the structural barrier includes a third electrode 340 and a conductive line 342 formed between the third electrode 340 and the first electrode 338. Accordingly, in this embodiment, the method for forming a circuit having a structural barrier, in accordance with the present teachings, includes electrically connecting 408 the structural barrier to the first electrode. However, as explained above, no such electrical connection is required in at least one embodiment of the present disclosure.

In the foregoing specification, specific embodiments have been described. However, one of ordinary skill in the art appreciates that various modifications and changes can be made without departing from the scope of the disclosure as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendment made during the pendency of this application and all equivalents of those claims as issued.

For the sake of brevity, conventional techniques related to semiconductor fabrication including those using conventional CMOS technology, CMOS devices, MOSFETs, and other functional aspects of a system or IC, and the individual system or IC operating components, and other processes such as ceramic or organic single layer and multi-layer board manufacturing may not be described in detail. Similarly, details regarding other conventional circuit manufacturing techniques such as sputtering processes, ink jet processes, and CD substrate printing processes are not provided herein for the sake of brevity. Furthermore, the connecting lines shown in the various figures contained herein are intended to represent example functional relationships and/or physical couplings between the various elements. It should be noted that many alternative or additional functional relationships or physical connections might be present in a practical embodiment. Moreover, the various IC embodiments described above may be produced or fabricated using conventional semiconductor processing techniques, e.g., well known CMOS techniques. Further, a variety of well-known and common semiconductor materials may be used, e.g., traditional metals such as aluminum, copper, gold, etc., polysilicon, silicon dioxide, silicon nitride, silicon, and the like.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%.

As used herein, the term “configured to”, “configured with”, “arranged to”, “arranged with”, “capable of” and any like or similar terms means that referenced circuit elements have an internal physical arrangement such as by virtue of a particular transistor technology used and/or physical coupling and/or connectivity with other circuit elements in an inactive state. This physical arrangement and/or physical coupling and/or connectivity while in the inactive state enables the circuit elements to perform stated functionality while in the active state of receiving and processing various signals at inputs of the circuit elements to generate signals at the output of the circuit elements. A device or structure that is “configured” in a certain way is configured in at least that way, but may also be configured in ways that are not described.

The above description refers to features being “connected” or “coupled” together. As used here and, unless expressly stated otherwise, “coupled” means that one feature is directly or indirectly joined to or is in direct or indirect communication with another feature, and not necessarily physically. As used herein, unless expressly stated otherwise, “connected” means that one feature is directly joined to or is in direct communication with another feature. For example, a first feature may be “coupled” to a plurality of other features, but all of those other features need not always be “connected” to each other; moreover, the first feature may connect different features to each other depending on the state of the first feature. Furthermore, although the various circuit schematics shown herein depict certain example arrangement of elements, additional intervening elements, devices, features, or components may be present in an actual embodiment, assuming that the functionality of the given circuit is not adversely affected.

In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. A circuit having a structure for inhibiting dendrite formation, the circuit comprising:
a first electrode disposed within a first area of the circuit, wherein the first electrode is configured to be coupled to an ionic source that forms ions when a first electric potential is applied to the first electrode;
a second electrode disposed within a second area of the circuit, wherein the second electrode is configured to receive a second electric potential that is less than the first electric potential and that causes the ions to migrate toward the second electrode to contribute to dendrite formation;
a structure disposed within a third area of the circuit, wherein the structure is configured to receive a third electric potential to create a barrier that inhibits the migration of at least some of the ions from the first electrode to the second electrode to inhibit the dendrite formation.

2. The circuit of claim 1, wherein the third electric potential is the same as or greater than the first electric potential.

3. The circuit of claim 1, wherein the first electrode is electrically connected to the structure.

4. The circuit of claim 1, wherein the first and second areas are in a same plane of the circuit.

5. The circuit of 4, wherein the structure comprises a third electrode and a set of conductive lines connecting the first and third electrodes.

6. The circuit of claim 1 further comprising:
a circuit board on which the first and second electrodes and the structure are mounted;
an electronic component mounted to the circuit board, the electronic component comprising:
an anode disposed in a first area of the electronic component;
a cathode disposed in a second area of the electronic component;
a barrier structure disposed in a third area of the electronic component between the first and second areas, wherein the barrier structure comprises a material that is more resistant to ion formation than material used to form the ionic source, and wherein the barrier structure is configured to be electrically connected to the anode.

7. The circuit of claim 1, wherein the first, second, and third areas are in different planes of the circuit.

8. The circuit of claim 7, wherein the first, second, and third areas are in different planes of at least one of a printed circuit board or a discrete electronic component.

9. The circuit of claim 6, wherein the first electrode is disposed in a surface layer of the printed circuit board, the second electrode is disposed in a ground layer of the printed circuit board, and the structure is disposed in a layer of the printed circuit board between the surface layer and the ground layer.

10. The circuit of claim 1, wherein the ionic source comprises a metal, which forms the ions.

11. The circuit of claim 10, wherein the circuit is formed in a printed circuit board, the first electrode is a first pad, and the second electrode is a second pad, and the metal that comprises the ionic source is a bonding material comprising silver.

12. The circuit of claim 1, wherein the ionic source comprises at least one of a conductive epoxy, a metal alloy, a metal and polymer combination, or a metal and ceramic combination.

13. The circuit of claim 1, wherein the structure is constructed using a material that inhibits dendrite formation.

14. The circuit of claim 1 further comprising a plurality of electronic components, wherein the first and second electrodes are formed in two different electronic components of the plurality of electronic components.

15. The circuit of claim 1, wherein the structure is constructed using a material that is less susceptible to forming ions than a material used to form the ionic source.

16. A method of manufacturing a circuit having a structure for inhibiting dendrite formation, the method comprising:
forming a first electrode within a first area of the circuit, wherein the first electrode is configured to be coupled to an ionic source that forms ions when a first electric potential is applied to the first electrode;
forming a second electrode within a second area of the circuit;
forming a structural barrier between the first and second electrodes to, when a second electric potential is applied to the structural barrier, inhibit the migration of at least some of the ions toward the second electrode in order to inhibit dendrite formation at the second electrode.

17. The method of claim 16, wherein first and second electrodes and the structural barrier are formed on a surface of the circuit.

18. The method of claim 16, wherein the circuit comprises a multi-layer circuit, and wherein the first and second electrodes and the structural barrier are formed in different layers of the multi-layer circuit.

19. The method of claim 16, wherein forming the structural barrier comprises forming a third electrode and forming a set of conductive lines between the first and third electrodes.

20. The method of claim 16 further comprising electrically connecting the structural barrier to the first electrode.
